(19) United States
(12) Patent Application Publication
(10) Pub. No.: US 2011/0049456 A1
(43) Pub. Date: Mar. 3, 2011

(54) PHASE CHANGE STRUCTURE WITH COMPOSITE DOPING FOR PHASE CHANGE MEMORY

(75) Inventors: HSIANG-LAN LUNG, DOBBS FERRY, NY (US); CHIEH-FANG CHEN, PANCIAO CITY (TW); YEN-HAO SHIH, ELMSFORD, NY (US); HUAI-YU CHENG, HSINCHU (TW); ERH-KUN LAI, ELMSFORD, NY (US); MING HSIU LEE, HSINCHU (TW); MATTHEW J. BREITWISCH, YORKTOWN HEIGHTS, NY (US); SIMONE RAO, NEW YORK, NY (US); CHUNG HON LAM, PEEKSKILL, NY (US)

(73) Assignees: Macronix International Co., Ltd., Hsinchu (TW); International Business Machines Corporation, Armonk, NY (US)

(21) Appl. No.: 12/553,784

(22) Filed: Sep. 3, 2009

(51) Int. Cl. H01L 45/00; H01L 21/06

(52) U.S. Cl. 257/2; 438/102; 257/E45.002; 257/E21.068

(57) ABSTRACT

A memory device is described using a composite doped phase change material between a first electrode and a second electrode. A memory element of phase change material, such as a chalcogenide, is between the first and second electrodes and has an active region. The phase change material has a first dopant, such as silicon oxide, characterized by tending to segregate from the phase change material on grain boundaries in the active region, and has a second dopant, such as silicon, characterized by causing an increase in recrystallization temperature of, and/or suppressing void formation in, the phase change material in the active region.

### PARTIES TO A JOINT RESEARCH AGREEMENT

International Business Machines Corporation, a New York corporation, and Macronix International Corporation, Ltd., a Taiwan corporation, are parties to a Joint Research Agreement.

### BACKGROUND OF THE INVENTION

1. Field of the Invention

The present invention relates to memory devices based on phase change materials including chalcogenide materials, and methods for manufacturing such devices.

2. Description of Related Art

Phase change based memory materials, like chalcogenide based materials and similar materials, can be caused to change between an amorphous phase and a crystalline phase by application of electrical current at levels suitable for implementation in integrated circuits. The amorphous phase is characterized by higher electrical resistivity than the crystalline phase, which can be readily sensed to indicate data. These properties have generated interest in using programmable resistive material to form nonvolatile memory circuits, which can be read and written with random access.

The change from the amorphous to the crystalline phase is generally a lower current operation. The change from crystalline to amorphous, referred to as reset herein, is generally a higher current operation, which includes a short high current density pulse to melt or breakdown the crystalline structure, after which the phase change material cools quickly, quenching the phase change process and allowing at least a portion of the phase change material to stabilize in the amorphous phase.

Research has progressed to provide memory devices that operate with low reset current by adjusting a doping concentration in phase change material, and by providing structures with very small dimensions. One problem with very small dimension phase change devices involves endurance. Specifically, memory cells made using phase change materials can fail as the composition of part of the phase change material slowly changes with time from the amorphous to the crystalline phase. For example, a memory cell in which the active region has been reset to a generally amorphous state may over time develop a distribution of crystalline regions in the active region. If these crystalline regions connect to form a low resistance path through the active region, when the memory cell is read, a lower resistance state will be detected and result in a data error. See, Gleixner, “Phase Change Memory Reliability”, tutorial. 22nd NVSMW, 2007.

Another problem with phase change memory cells arises from the manufacturability issues arising from the polycrystalline phase of the material. A large grain size can result in void formation that interferes with current flow in unexpected ways, and can cause failure.

The magnitude of the reset current needed to induce a phase change can be affected by doping the phase change material. Chalcogenides and other phase change materials can be doped with impurities to modify conductivity, transition temperature, melting temperature, and other properties of memory elements using the doped chalcogenides. Representative impurities used for doping chalcogenides include nitrogen, silicon, oxygen, silicon oxide, silicon nitride, copper, silver, gold, aluminum, aluminum oxide, tantalum, tantalum oxide, tantalum nitride, titanium and titanium oxide. See, e.g., U.S. Pat. No. 6,800,504 (metal doping), and U.S. Patent Application Publication No. U.S. 2005/0029502 (nitrogen doping).

U.S. Pat. No. 6,087,674, and its parent U.S. Pat. No. 5,825,046 by Ovshinsky et al., describe forming composite memory material in which phase change material is mixed with relatively high concentrations of dielectric material in order to manage the resistance of the composite memory material. The nature of the composite memory material described in these patents is not clear, because it describes composites as layered structures as well as mixed structures. The dielectric materials described in these patents cover a very broad range.

A number of researchers have investigated the use of silicon oxide doping of chalcogenide material for the purposes of reducing the reset current needed for operation of the memory devices. See, Ryu, et al, “SiO₂ Incorporation Effects in Ge₂Sb₂Te₅ Films Prepared by Magnetron Sputtering for Phase Change Random Access Memory Devices,” Electrochemical and Solid-State Letters, 9 (8) G259-G261, (2006); Lee et al., “Separate domain formation in Ge₂Sb₂Te₅—SiOₓ mixed layer,” Appl. Phys. Lett. 89,163503 (2006); Czubatyj et al., “Current Reduction in Ovonic Memory Devices,” E*PCOS06 (2006); and Noh et al., “Modification of Ge₂Sb₂Te₅ by the Addition of SiOₓ for Improved Operation of Phase Change Random Access Memory,” Mater. Res. Soc. Symp. Proc. Vol. 888 (2006). These references suggest that relatively low concentrations of silicon oxide doping in Ge₂Sb₂Te₅ result in substantial increases in resistance and corresponding reductions in reset current. The Czubatyj et al. article suggests that the improvement in resistance in a silicon oxide doped GST alloy saturates at about 10 vol % (6.7 at %), and reports that doping concentrations up to 30 vol % silicon oxide had been tested, without providing details. The Lee et al. publication describes a phenomenon at relatively high doping concentrations around 8.4 at %, by which the silicon oxide appears to separate from the GST after high-temperature annealing to form domains of GST surrounded by boundaries that are primarily silicon oxide. Doping with silicon dioxide also results in reduction in grain size in the polycrystalline phase of the material, and improves manufacturability.

Hudgens, U.S. Patent Application Publication No. US 2005/0029502 describes a composite doped GST, where nitrogen or nitrogen and oxygen are alleged to cause reduction in grain size, while a second dopant, such as titanium, is applied in a manner that increases the set programming speed. The second dopant in Hudgens is applied to offset an increase in the time needed for set programming caused by nitrogen doping. However, it is found that gas phase dopants like nitrogen and oxygen, while causing a reduction in grain size in the deposited material, have not been reliable, and result in void formations in the material during use.

Chen et al., U.S. Pat. No. 7,501,648 entitled PHASE CHANGE MATERIALS AND ASSOCIATED MEMORY DEVICES, issued 10 Mar. 2009, describes phase change material doped using nitride compounds, to affect transition speeds.

Our co-pending U.S. Patent Application entitled DIELECTRIC MESH ISOLATED PHASE CHANGE STRUCTURE FOR PHASE CHANGE MEMORY, application Ser. No. 12/286,874, filed 2 Oct. 2008, describes the use of silicon dioxide doping in relatively high concentrations and addresses some of the issues discussed above related to changes in composition of the phase change materials. application Ser. No. 12/286,874 is incorporated by reference as if fully set forth herein. Although substantial benefits are achieved as taught in application Ser. No. 12/286,874 from relatively high concentration doping with silicon dioxide, as compared with nitrogen, including reduction in grain size in the polycrystalline phase and suppression of the formation of multiple crystalline phases, endurance issues still arise.

It is therefore desirable to provide memory cells having good data retention and very high endurance.

### SUMMARY OF THE INVENTION

A memory device is described herein with composite doping. The device includes a first electrode, a phase change material, such as a chalcogenide, in contact with the first electrode, and a second electrode in contact with the phase change material. The phase change material comprises a first dopant characterized by tending to segregate on grain boundaries in the active region, and a second dopant characterized by bonding with an element or elements of the phase change material in the active region to improve endurance, such as by causing an increase in recrystallization temperature of, and/or suppressing void formation in, the phase change material in the active region.

The first dopant comprises a stable, segregating material such as a dielectric, which can be selected for a chalcogenide based memory material, from silicon oxide, aluminum oxide, silicon carbide and silicon nitride. The second dopant comprises a material that forms relatively strong bonds with an element of the phase change material, increasing the melting temperature and the recrystallization temperature, which can improve endurance and retention, and suppressing void formation under the thermal stress in the active region, which can prevent device failure cause by such voids.

The stoichiometry of a phase change material tends to change inside the active region of the device, relative to that outside the active region because of the more extreme thermal conditions there, as the materials tend to migrate to more stable combinations according to the thermal environment. By doping the phase change material with a reactive dopant that tends to strengthen the phase change material, such as by forming a compound having a higher melting point or having a higher recrystallization temperature at which amorphous phase to crystalline phase transition occurs, in the active region, the endurance and retention of the memory device are dramatically improved.

For example, for a chalcogenide including Te and Sb, the second dopant is a reactive material like Si that bonds with the Te with a bonding energy greater than a bonding energy between the Te and the Sb. This may be a result of formation in the active region of a mixture of materials including higher melting point Si—Te compounds that tend to stabilize the microstructure in the active region, suppressing void formation, and resulting in higher endurance and better data retention.

Other reactive materials can include Scandium, Titanium, Vanadium, Chromium, Manganese, Iron, and Gallium, depending on the bulk phase change material chosen and other factors.

In a device described herein the phase change material comprises GeₓSb_{y}Te_{z}, where nominally as deposited, x=2, y=2 and z=5, the first dopant is silicon dioxide having a concentration in a range of 10 to 20 at %, and the second dopant is silicon having concentration in a range of 3 to 12 at %.

A manufacturing method for composite doped memory devices is described as well, including forming a first electrode and a second electrode; forming a body of phase change material between the first and second electrodes and having an active region, the phase change material having a first dopant characterized by tending to segregate from the phase change material on grain boundaries in the active region, and having a second dopant characterized by bonding with an element of the phase change material in the active region with a relatively strong bond compared to the bonding energy of said element with other elements of the phase change material. A step can be applied to heat the active region to cause the first dopant to segregate from the phase change material within the active region, or the segregation can occur as a result of normal operation of the device. The step of forming a body of phase change material with the first and second dopants can include a multi-compound sputtering process, using one composite target or multiple targets.

Other features, combinations of features, aspects and advantages of the technology described herein can be seen in the drawings, the detailed description and the claims which follow.

### BRIEF DESCRIPTION OF THE DRAWINGS

FIG. 1 illustrates a mushroom style memory cell as described herein having active regions comprising a composite doped phase change material.

FIG. 2 is a transmission electron microscope image of a mushroom style memory cell, with an undoped Ge₂Sb₂Te₅ memory element after 1 million cycles, showing failure due to void formation.

FIG. 3 is a transmission electron microscope image of a mushroom style memory cell, with a silicon dioxide doped Ge₂Sb₂Te₅ memory element after 10 million cycles, showing failure due to void formation.

FIG. 4 is a transmission electron microscope image of a mushroom style memory cell, with a silicon dioxide and silicon doped Ge₂Sb₂Te₅ memory element after 10 billion cycles, showing voids formation outside an active region which do not cause failure.

FIG. 5 is a simplified flowchart of a manufacturing process described herein.

FIGS. 6A-6D illustrate stages of a manufacturing process for formation of the composite-doped memory cell as described herein.

FIG. 7 illustrates a bridge type memory cell structure using a phase change material with a composite-doped memory material in the active region as described herein.

FIG. 8 illustrates an “active in via” type memory cell structure using a phase change material with a composite-doped memory material in the active region as described herein.

FIG. 9 illustrates a pore type memory cell structure using a phase change material with a composite-doped memory material in the active region as described herein.

FIG. 10 is a simplified block diagram of an integrated circuit memory device including phase change memory cells as described herein.

FIG. 11 is a simplified circuit diagram of a memory array including phase change memory cells as described herein.

### DETAILED DESCRIPTION

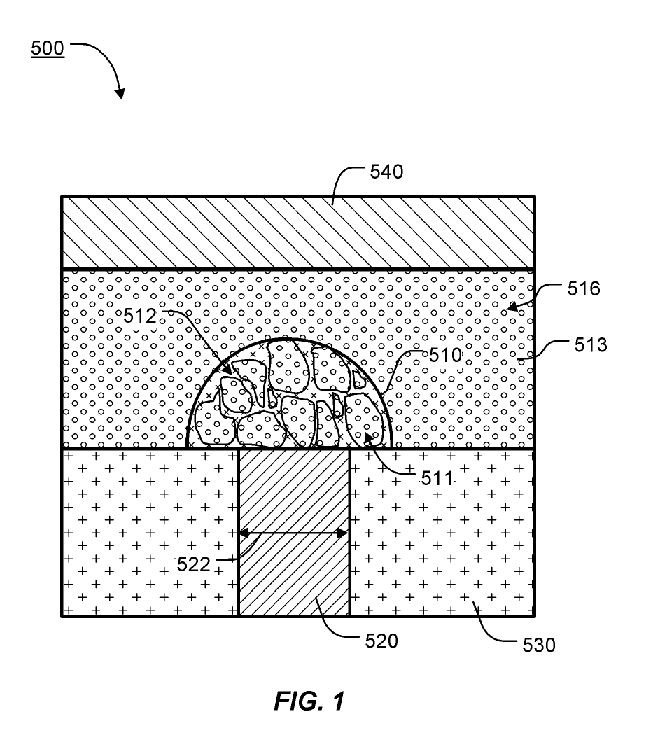

A detailed description of the present invention is provided with reference to FIGS. 1-11.

FIG. 1 illustrates a cross-sectional view of a memory cell 500 having a composite doped active region 510 comprising phase change domains 511 within a dielectric-rich mesh 512 caused by segregation of the first dopant on grain boundaries of the phase change material, and a more stable phase change material having a higher recrystallization temperature in the active region as a result of the second reactive dopant.

The memory cell 500 includes a first electrode 520 extending through dielectric 530 to contact a bottom surface of the memory element 516, and a second electrode 540 on the memory element 516 consisting of a doped phase change material. The first and second electrodes 520, 540 may comprise, for example, TiN or TaN. Alternatively, the first and second electrodes 520, 540 may each be W, WN, TiAlN or TaAlN, or comprise, for further examples, one or more elements selected from the group consisting of doped-Si, Si, C, Ge, Cr, Ti, W, Mo, Al, Ta, Cu, Pt, Ir, La, Ni, N, O, and Ru and combinations thereof.

In the illustrated embodiment the dielectric 530 comprises SiN. Alternatively, other dielectric materials may be used.

The phase change material of memory element 516 in this example comprises Ge₂Sb₂Te₅ material doped with a material that tends to segregate on grain boundaries from the Ge₂Sb₂Te₅, such as 10 to 20 atomic percent (at %) silicon oxide and a reactive material that tends to form strong bonds with an element of the Ge₂Sb₂Te₅, such as 3 to 15 at % silicon. Other chalcogenides, reactive materials and segregating materials may be used as well. As can be seen in the FIG. 1, the width 522 (which in some embodiments is a diameter) of the first electrode 520 is less than that of the memory element 516 and top electrode 540, and thus current is concentrated in the portion of the memory element 516 adjacent the first electrode 520, resulting in the active region 510 as shown. The memory element 516 also includes an inactive region 513 outside the active region 510. The inactive region 513 tends to remain in a polycrystalline state with small grain size.

The active region 510 comprises phase change domains 511 within a dielectric-rich mesh 512. The dielectric-rich mesh 512 comprises a higher concentration of silicon oxide material than that of the inactive region 513, and the phase change domains 511 comprise a higher concentration of chalcogenide material than that of the inactive region 513.

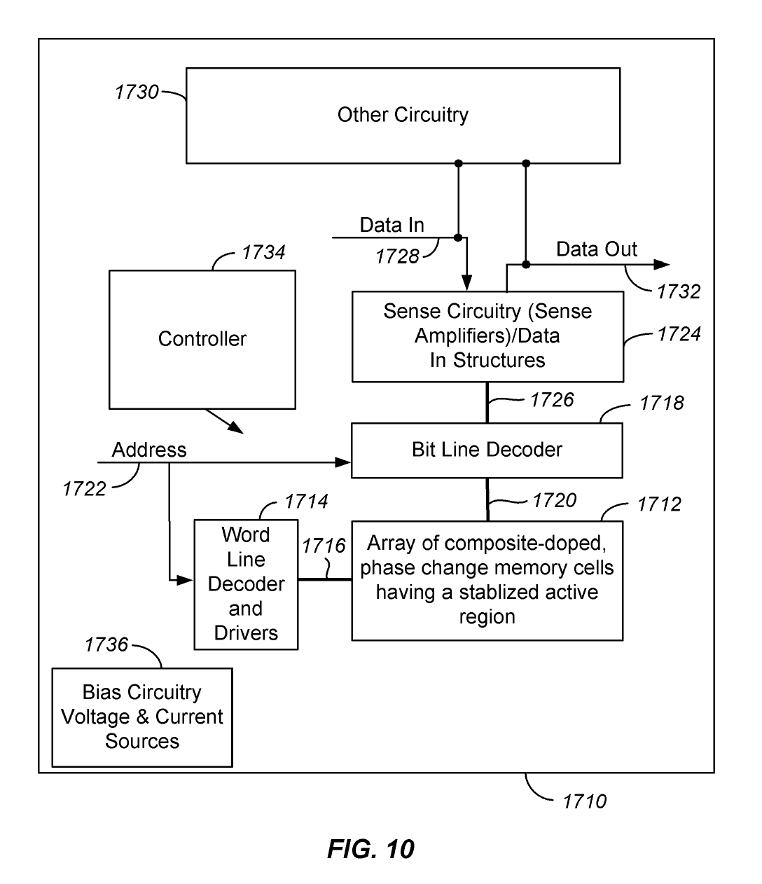

In a reset operation of the memory cell 500, bias circuitry (See, for example, bias circuitry voltage and current sources 1736 of FIG. 10 with the accompanying controller 1734) coupled to the first and second electrodes 520, 540 induces a current to flow between the first and second electrodes 520, 540 via the memory element 516 sufficient to induce a high resistance generally amorphous phase in the phase change domains 511 of the active region 510 to establish a high resistance reset state in the memory cell 500.

GST based memory materials generally include two crystalline phases, a lower transition temperature FCC (face-centered cubic) phase and a higher transition temperature HCP (hexagonal close-packed) phase, the HCP phase having a higher density than the FCC phase. In general the transition from the FCC phase to the HCP phase is not desirable since the resulting decrease in memory material volume causes stresses within the memory material and at the interfaces between electrodes and the memory material. The transition of undoped Ge₂Sb₂Te₅ from the FCC phase to the HCP phase occurs below an anneal temperature of 400° C. Since a memory cell comprising undoped Ge₂Sb₂Te₅ may experience a temperature of 400° C. or more during set operations, issues can arise in the reliability of the memory cell due to this transition to the HCP state. Also, the speed of transition to the HCP phase will be slower.

Over the life of a memory cell, these volume shifts can encourage formation of voids in the active region, leading to device failure.

It is found that Ge₂Sb₂Te₅ material having 10 at % and 20 at % silicon oxide, remains in the FCC state at an anneal temperature of up to 400° C. Moreover, doped Ge₂Sb₂Te₅ material having 10 at % and 20 at % silicon oxide has a smaller grain size than undoped Ge₂Sb₂Te₅. See, U.S. patent application entitled DIELECTRIC MESH ISOLATED PHASE CHANGE STRUCTURE FOR PHASE CHANGE MEMORY, application Ser. No. 12/286,874, incorporated by reference herein.

As a result, memory cells comprising doped Ge₂Sb₂Te₅ material having 10 to 20 at % silicon oxide annealed at temperatures as high as 400° C. during set operations avoid the higher density HCP state, and thus experience less mechanical stress and have increased reliability and higher switching speed, compared to memory cells comprising undoped Ge₂Sb₂Te₅.

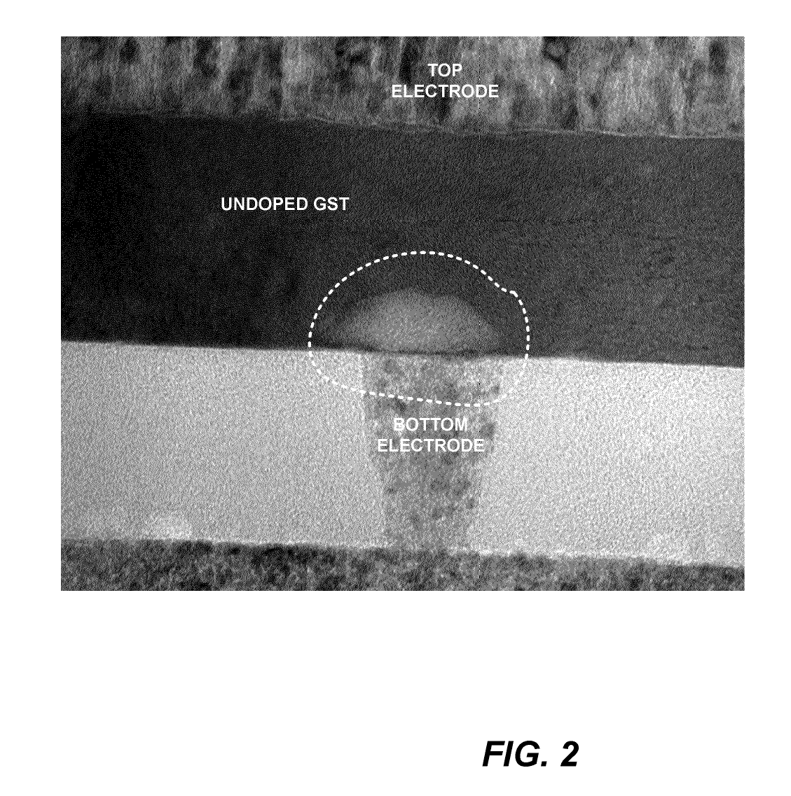

FIG. 2 is a transmission electron microscope image of a memory cell like that of FIG. 1, in which the memory element consists of undoped Ge₂Sb₂Te₅, taken after the cell had been subjected to 1 million (1M) set/reset cycles. In the region circled by the dotted line in the memory element in contact with the bottom electrode, a large void can be seen as a light-colored region inside the darker memory material. This void causes device failure, preventing the style of phase change material from being utilized for systems requiring high endurance.

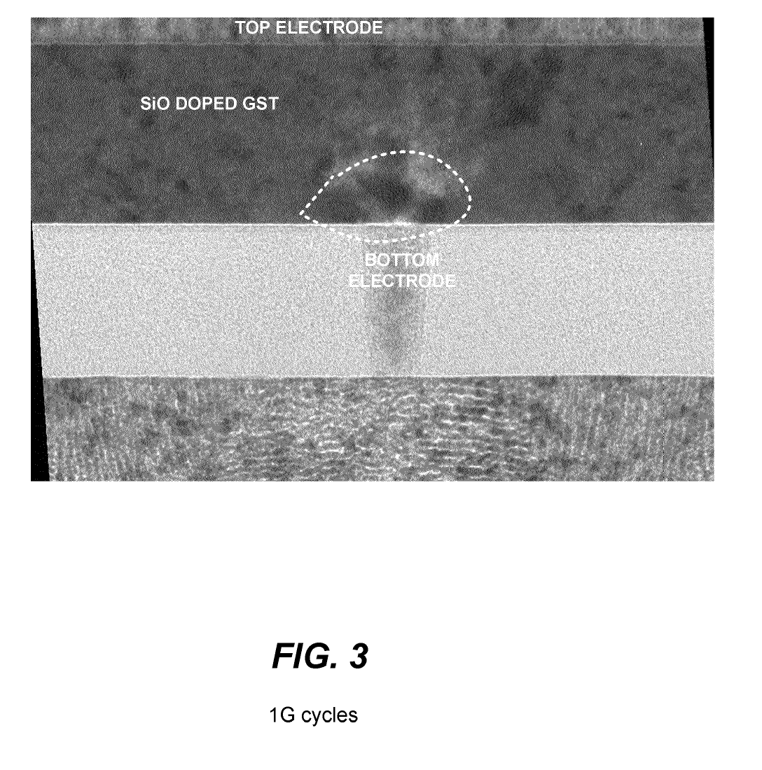

FIG. 3 is a transmission electron microscope image of a memory cell like that of FIG. 1, in which the memory element consists of Ge₂Sb₂Te₅ doped with about 10 percent silicon dioxide, taken after the cell had been subjected to 1 billion (1 G) set/reset cycles. In the region circled by the dotted line in the memory element near the contact surface on bottom electrode, smaller voids are seen as light-colored regions in the darker memory material. These small voids also cause device failure. However, the silicon dioxide doping leads to significantly greater endurance as compared to the undoped material.

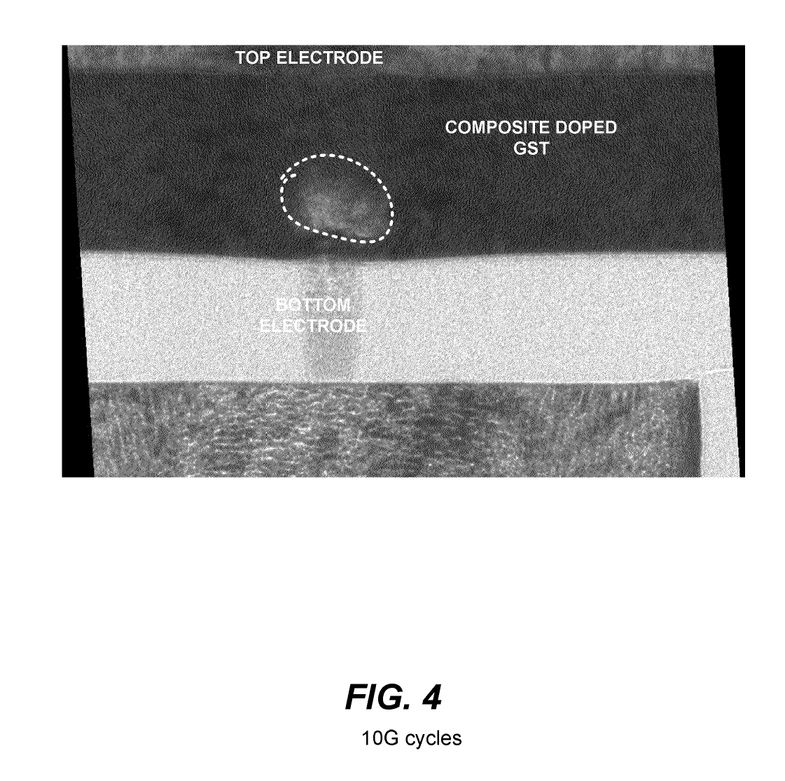

FIG. 4 is a transmission electron microscope image of a memory cell like that of FIG. 1, in which the memory element consists of Ge₂Sb₂Te₅ with composite doping, including about 10 percent silicon dioxide and about 7 percent silicon. This image is taken after the salad been subjected to 10 billion (10 G) set/reset cycles. Void formation can be seen as light-colored regions inside the darker memory material in the region circled by the dotted line. In this cell, the void formation is spaced away from the contact surface on the bottom electrode and does not cause device failure. The reactive doping strengthens or stabilizes the active region on the contact surface of the bottom electrode in the memory material, suppressing void formation, and dramatically increasing the endurance of the cell.

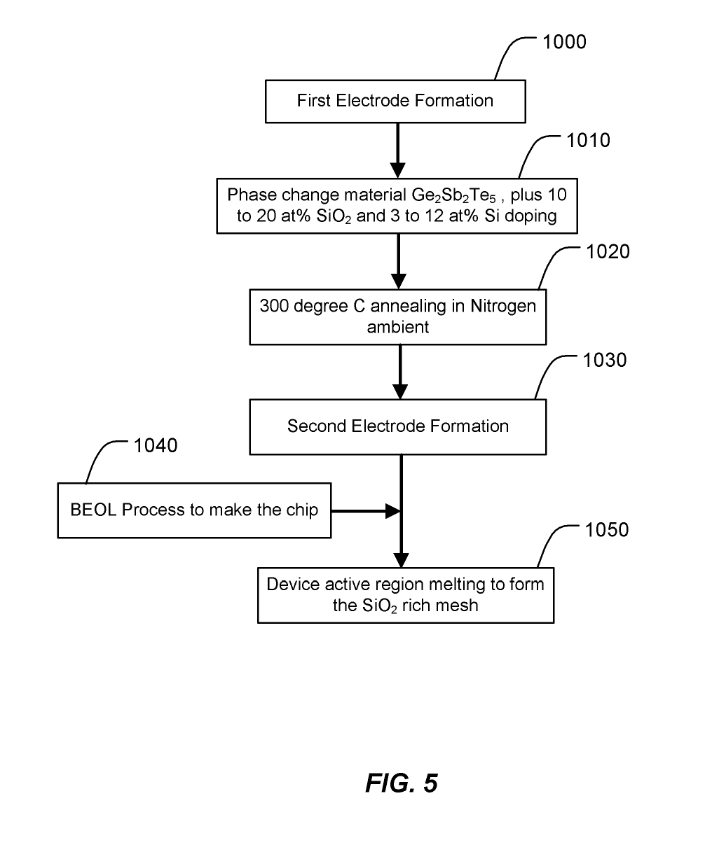

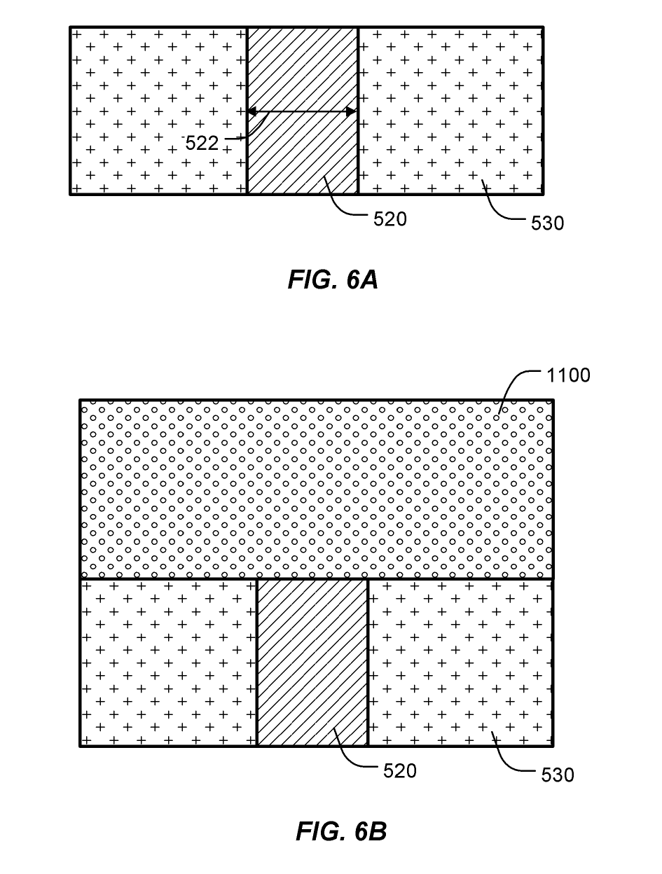

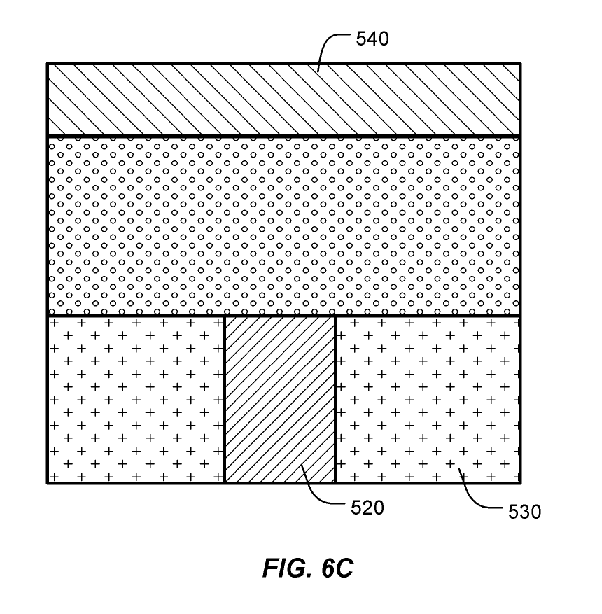

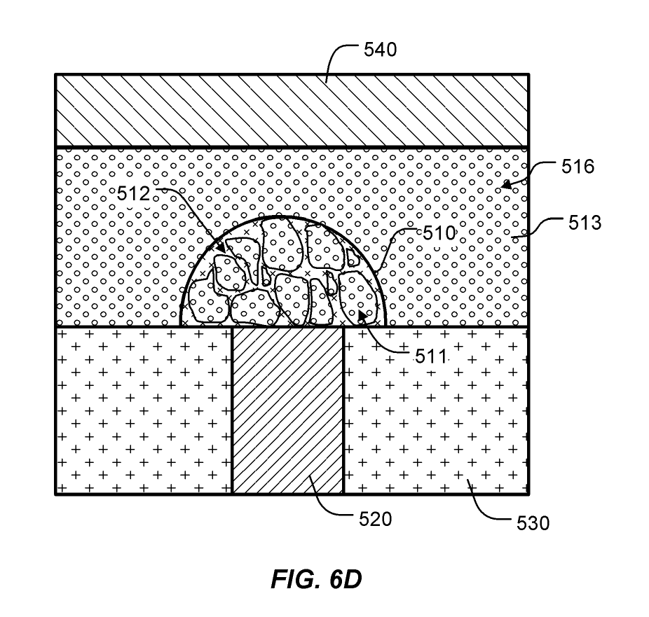

FIG. 5 illustrates a process flow diagram and FIGS. 6A-6D illustrate steps in a manufacturing process for manufacturing a memory cell comprising Ge₂Sb₂Te₅ material doped with 10 to 20 at % silicon oxide, and 3 to 15 at % silicon, as described herein.

At step 1000 the first electrode 520 having a width or diameter 522 is formed extending through dielectric 530, resulting in the structure illustrated in the cross-sectional view of FIG. 6A. In the illustrated embodiment, the first electrode 520 comprises TiN and the dielectric 530 comprises SiN. In some embodiments the first electrode 520 has a sublithographic width or diameter 522.

The first electrode 520 extends through dielectric 530 to underlying access circuitry (not shown). The underlying access circuitry can be formed by standard processes as known in the art, and the configuration of elements of the access circuitry depends upon the array configuration in which the memory cells described herein are implemented. Generally, the access circuitry may include access devices such as transistors and diodes, word lines and sources lines, conductive plugs, and doped regions within a semiconductor substrate.

The first electrode 520 and the dielectric layer 530 can be formed, for example, using methods, materials, and processes as disclosed in U.S. patent application Ser. No. 11/764,678 filed on 18 Jun. 2007 entitled “Method for Manufacturing a Phase Change Memory Device with Pillar Bottom Electrode” (now U.S. Publication 2008/0191187), which is incorporated by reference herein. For example, a layer of electrode material can be formed on the top surface of access circuitry (not shown), followed by patterning of a layer of photoresist on the electrode layer using standard photolithographic techniques so as to form a mask of photoresist overlying the location of the first electrode 520. Next the mask of photoresist is trimmed, using for example oxygen plasma, to form a mask structure having sublithographic dimensions overlying the location of the first electrode 520. Then the layer of electrode material is etched using the trimmed mask of photoresist, thereby forming the first electrode 520 having a sublithographic diameter 522. Next dielectric material 530 is formed and planarized, resulting in the structure illustrated in FIG. 6A.

As another example, the first electrode 520 and dielectric 530 can be formed using methods, materials, and processes as disclosed in U.S. patent application Ser. No. 11/855,979 filed on 14 Sep. 2007 entitled “Phase Change Memory Cell in Via Array with Self-Aligned, Self-Converged Bottom Electrode and Method for Manufacturing” (now U.S. Publication 2009/0072215) which is incorporated by reference herein. For example, the dielectric 530 can be formed on the top surface of access circuitry followed by sequentially forming an isolation layer and a sacrificial layer. Next, a mask having openings close to or equal to the minimum feature size of the process used to create the mask is formed on the sacrificial layer, the openings overlying the location of the first electrode 520. The isolation layer and the sacrificial layers are then selectively etched using the mask, thereby forming a via in the isolation and sacrificial layers and exposing a top surface of the dielectric layer 530. After removal of the mask, a selective undercutting etch is performed on the via such that the isolation layer is etched while leaving the sacrificial layer and the dielectric layer 530 intact. A fill material is then formed in the via, which due to the selective undercutting etch process results in a self-aligned void in the fill material being formed within the via. Next, an anisotropic etching process is performed on the fill material to open the void, and etching continues until the dielectric layer 530 is exposed in the region below the void, thereby forming a sidewall spacer comprising fill material within the via. The sidewall spacer has an opening dimension substantially determined by the dimensions of the void, and thus can be less than the minimum feature size of a lithographic process. Next, the dielectric layer 530 is etched using the sidewall spacers as an etch mask, thereby forming an opening in the dielectric layer 530 having a diameter less than the minimum feature size. Next, an electrode layer is formed within the openings in the dielectric layer 530. A planarizing process, such as chemical mechanical polishing CMP, is then performed to remove the isolation layer and the sacrificial layer and to form the first electrode 520, resulting in the structure illustrated in FIG. 6A.

At step 1010 a layer of phase change material 1100 comprising doped Ge₂Sb₂Te₅ material having 10 to 20 at % silicon oxide and 3 to 15 at % silicon is deposited on the first electrode 520 and dielectric 530 of FIG. 6A, resulting in the structure illustrated in FIG. 6B. The deposition of Ge₂Sb₂Te₅ and silicon oxide may be carried out by co-sputtering of a GST target with for one example, a DC power of 10 Watts, a SiO₂ target with an RF power of 10 to 115 Watts, and a Si target with an RF power in a range similar to that of the SiO₂ target, all in an argon atmosphere. In alternatives, the memory material can be sputtered using a composite target. Also, other deposition technologies can be applied, including chemical vapor deposition, atomic layer deposition and so on.

Next, at step 1020 annealing is performed to crystallize the phase change material. In the illustrated embodiment the thermal annealing step is carried out at 300° C. for 100 seconds in a nitrogen ambient. Alternatively, since subsequent back-end-of-line processes performed to complete the device may include high temperature cycles and or a thermal annealing step depending upon the manufacturing techniques used to complete the device, in some embodiments the annealing at step 1020 may accomplished by following processes, and no separate annealing step is added to the manufacturing line.

Next, at step 1030 second electrode 540 is formed, resulting in the structure illustrated in FIG. 6C. In the illustrated embodiment the second electrode 540 comprises TiN.

Next, at step 1040 back-end-of-line (BEOL) processing is performed to complete the semiconductor process steps of the chip. The BEOL processes can be standard processes as known in the art, and the processes performed depend upon the configuration of the chip in which the memory cell is implemented. Generally, the structures formed by BEOL processes may include contacts, inter-layer dielectrics and various metal layers for interconnections on the chip including circuitry to couple the memory cell to periphery circuitry. These BEOL processes may include deposition of dielectric material at elevated temperatures, such as depositing SiN at 400° C. or high density plasma HDP oxide deposition at temperatures of 500° C. or greater. As a result of these processes, control circuits and biasing circuits as shown in FIG. 10 are formed on the device.

Next, at step 1050 current is applied to the memory cells in the array to melt the active region, and allow cooling to form the dielectric mesh, such as by reset cycling (or set/reset cycling) on the memory cell 500 using the control circuits and bias circuits to melt and cool the active regions at least once, or enough times to cause formation of the dielectric mesh. The cycling may or may not be needed in a given implementation using composite doping as described here. The number of cycles needed to form the active region 510 comprising phase change domains 511 within a dielectric-rich mesh 512, may be, for example, 1 to 100 times. The resulting structure is illustrated in FIG. 6D. The cycling consists of applying appropriate voltage pulses to the first and second electrodes 520, 540 to induce a current in the memory element sufficient to melt the material in the active region, and followed by an interval with no or small current allowing the active region to cool. The melting/cooling cycling can be implemented using the set/reset circuitry on the device, by applying one or more reset pulses sufficient to melt the active region, or a sequence of set and reset pulses. In addition, the control circuits and bias circuits may be implemented to execute a mesh forming mode, using voltage levels and pulse lengths that differ from the normal set/reset cycling used during device operation. In yet another alternative, the melting/cooling cycling may be executed using equipment in the manufacturing line that connects to the chips during manufacture, such as test equipment, to set voltage magnitudes and pulse heights.

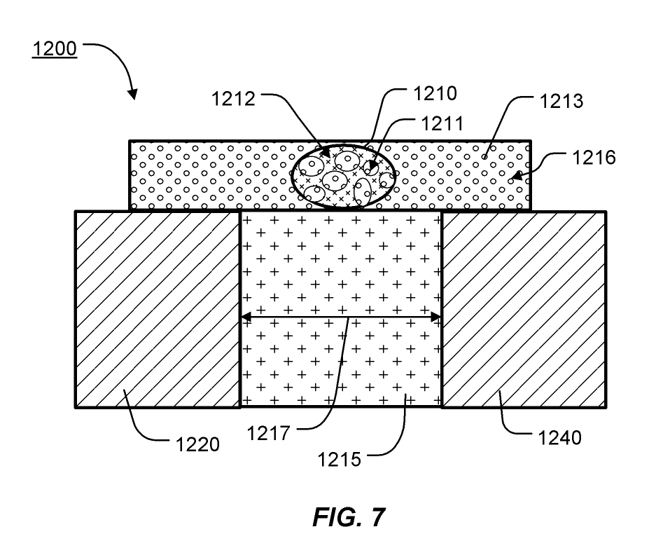

FIGS. 7-9 illustrate alternative structures for composite doped memory cells, having an active region comprising phase change domains within a dielectric-rich mesh. The materials described above with reference to the elements of FIG. 1 may be implemented in the memory cells of FIGS. 7-9, and thus a detailed description of these materials is not repeated.

FIG. 7 illustrates a cross-sectional view of a memory cell 1200 having a composite-doped active region 1210 comprising phase change domains 1211 within a dielectric-rich mesh 1212. The memory cell 1200 includes a dielectric spacer 1215 separating first and second electrodes 1220, 1240. Memory element 1216 extends across the dielectric spacer 1215 to contact the first and second electrodes 1220, 1240, thereby defining an inter-electrode current path between the first and second electrodes 1220, 1240 having a path length defined by the width 1217 of the dielectric spacer 1215. In operation, as current passes between the first and second electrodes 1220, 1240 and through the memory element 1216, the active region 1210 heats up more quickly than the remainder 1213 of the memory element 1216.

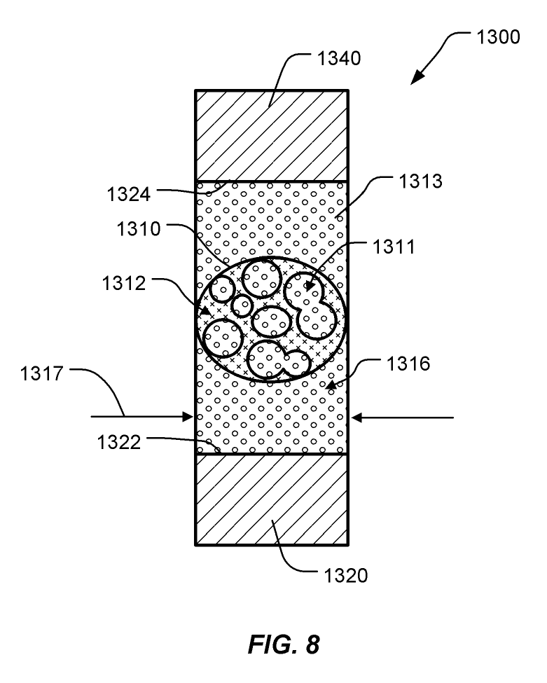

FIG. 8 illustrates a cross-sectional view of a memory cell 1300 having a composite-doped active region 1310 comprising phase change domains 1311 within a dielectric-rich mesh 1312. The memory cell 1300 includes a pillar shaped memory element 1316 contacting first and second electrodes 1320, 1340 at top and bottom surfaces 1322, 1324, respectively. The memory element 1316 has a width 1317 substantially the same as that of the first and second electrodes 1320, 1340 to define a multi-layer pillar surrounded by dielectric (not shown). As used herein, the term “substantially” is intended to accommodate manufacturing tolerances. In operation, as current passes between the first and second electrodes 1320, 1340 and through the memory element 1316, the active region 1310 heats up more quickly than the remainder 1313 of the memory element.

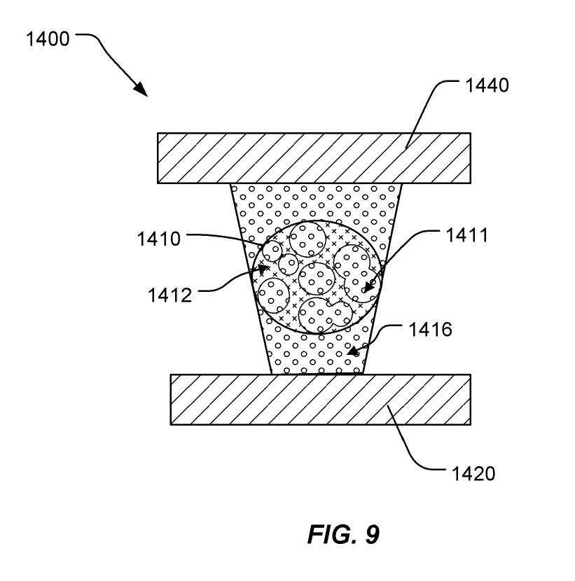

FIG. 9 illustrates a cross-sectional view of a memory cell 1400 having a composite-doped active region 1410 comprising phase change domains 1411 within a dielectric-rich mesh 1412. The memory cell 1400 includes a pore-type memory element 1416 surrounded by dielectric (not shown) contacting first and second electrodes 1420, 1440 at top and bottom surfaces respectively. The memory element has a width less than that of the first and second electrodes, and in operation as current passes between the first and second electrodes and through the memory element the active region heats up more quickly than the remainder of the memory element.

As will be understood, the present invention is not limited to the memory cell structures described herein and generally includes memory cells having an active region comprising phase change domains within a dielectric-rich mesh.

FIG. 10 is a simplified block diagram of an integrated circuit 1710 including a memory array 1712 implemented using memory cells having a composite-doped active region as described herein. A word line decoder 1714 having read, set and reset modes is coupled to and in electrical communication with a plurality of word lines 1716 arranged along rows in the memory array 1712. A bit line (column) decoder 1718 is in electrical communication with a plurality of bit lines 1720 arranged along columns in the array 1712 for reading, setting, and resetting the phase change memory cells (not shown) in array 1712. Addresses are supplied on bus 1722 to word line decoder and drivers 1714 and bit line decoder 1718. Sense circuitry (Sense amplifiers) and data-in structures in block 1724, including voltage and/or current sources for the read, set, and reset modes are coupled to bit line decoder 1718 via data bus 1726. Data is supplied via a data-in line 1728 from input/output ports on integrated circuit 1710, or from other data sources internal or external to integrated circuit 1710, to data-in structures in block 1724. Other circuitry 1730 may be included on integrated circuit 1710, such as a general purpose processor or special purpose application circuitry, or a combination of modules providing system-on-a-chip functionality supported by array 1712. Data is supplied via a data-out line 1732 from the sense amplifiers in block 1724 to input/output ports on integrated circuit 1710, or to other data destinations internal or external to integrated circuit 1710.

A controller 1734 implemented in this example, using a bias arrangement state machine, controls the application of bias circuitry voltage and current sources 1736 for the application of bias arrangements including read, program, erase, erase verify and program verify voltages and/or currents for the word lines and bit lines. In addition, bias arrangements for melting/cooling cycling may be implemented as mentioned above. Controller 1734 may be implemented using special-purpose logic circuitry as known in the art. In alternative embodiments, controller 1734 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 1734.

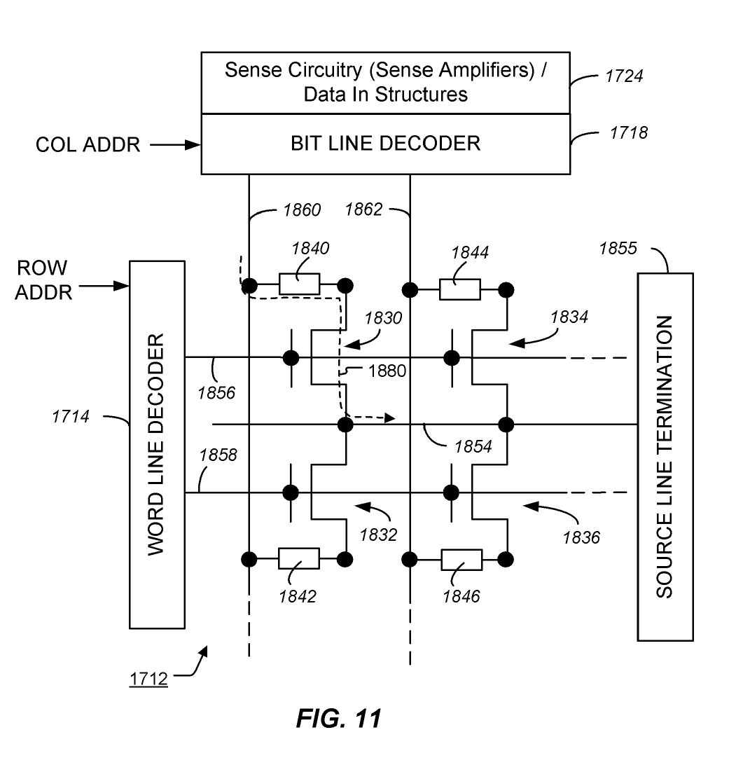

As shown in FIG. 11, each of the memory cells of array 1712 includes an access transistor (or other access device such as a diode) and memory element having an active region comprising phase change domains within a dielectric-rich mesh. In FIG. 11 four memory cells 1830, 1832, 1834, 1836 having respective memory elements 1840, 1842, 1844, 1846 are illustrated, representing a small section of an array that can include millions of memory cells.

Sources of each of the access transistors of memory cells 1830, 1832, 1834, 1836 are connected in common to source line 1854 that terminates in a source line termination circuit 1855, such as a ground terminal. In another embodiment the source lines of the access devices are not electrically connected, but independently controllable. The source line termination circuit 1855 may include bias circuitry such as voltage sources and current sources, and decoding circuits for applying bias arrangements, other than ground, to the source line 1854 in some embodiments.

A plurality of word lines including word lines 1856, 1858 extend in parallel along a first direction. Word lines 1856, 1858 are in electrical communication with word line decoder 1714. The gates of access transistors of memory cells 1830 and 1834 are connected to word line 1856, and the gates of access transistors of memory cells 1832 and 1836 are connected in common to word line 1858.

A plurality of bit lines including bit lines 1860, 1862 extend in parallel in a second direction and are in electrical communication with bit line decoder 1718. In the illustrated embodiment each of the memory elements are arranged between the drain of the corresponding access device and the corresponding bit line. Alternatively, the memory elements may be on the source side of the corresponding access device.

It will be understood that the memory array 1712 is not limited to the array configuration illustrated in FIG. 11, and additional array configurations can also be used. Additionally, instead of MOS transistors, bipolar transistors or diodes may be used as access devices in some embodiments.

In operation, each of the memory cells in the array 1712 stores data depending upon the resistance of the corresponding memory element. The data value may be determined, for example, by comparison of current on a bit line for a selected memory cell to that of a suitable reference current by sense amplifiers of sense circuitry 1724. The reference current can be established so that a predetermined range of currents correspond to a logical “0”, and a differing range of currents correspond to a logical “1”.

Reading or writing to a memory cell of array 1712, therefore, can be achieved by applying a suitable voltage to one of word lines 1858, 1856 and coupling one of bit lines 1860, 1862 to a voltage source so that current flows through the selected memory cell. For example, a current path 1880 through a selected memory cell (in this example memory cell 1830 and corresponding memory element 1840) is established by applying voltages to the bit line 1860, word line 1856, and source line 1854 sufficient to turn on the access transistor of memory cell 1830 and induce current in path 1880 to flow from the bit line 1860 to the source line 1854, or vice-versa. The level and duration of the voltages applied is dependent upon the operation performed, e.g. a reading operation or a writing operation.

In a reset (or erase) operation of the memory cell 1830, word line decoder 1714 facilitates providing word line 1856 with a suitable voltage pulse to turn on the access transistor of the memory cell 1830. Bit line decoder 1718 facilitates supplying a voltage pulse to bit line 1860 of suitable amplitude and duration to induce a current to flow though the memory element 1840, the current raising the temperature of the active region of the memory element 1840 above the transition temperature of the phase change material and also above the melting temperature to place the phase change material of the active region in a liquid state. The current is then terminated, for example by terminating the voltage pulses on the bit line 1860 and on the word line 1856, resulting in a relatively quick quenching time as the active region cools to a high resistance generally amorphous phase in the phase change material in the active region to establish a high resistance reset state in the memory cell 1830. The reset operation can also comprise more than one pulse, for example using a pair of pulses.

In a set (or program) operation of the selected memory cell 1830, word line decoder 1714 facilitates providing word line 1856 with a suitable voltage pulse to turn on the access transistor of the memory cell 1830. Bit line decoder 1718 facilitates supplying a voltage pulse to bit line 1860 of suitable amplitude and duration to induce a current to flow through the memory element 1840, the current pulse sufficient to raise the temperature of the active region above the transition temperature and cause a transition in the phase change material in the active region from the high resistance generally amorphous condition into a low resistance generally crystalline condition, this transition lowering the resistance of the memory element 1840 and setting the memory cell 1830 to the low resistance state.

In a read (or sense) operation of the data value stored in the memory cell 1830, word line decoder 1714 facilitates providing word line 1856 with a suitable voltage pulse to turn on the access transistor of the memory cell 1830. Bit line decoder 1718 facilitates supplying a voltage to bit line 1860 of suitable amplitude and duration to induce current to flow through the memory element 1840 that does not result in the memory element undergoing a change in resistive state. The current on the bit line 1860 and through the memory cell 1830 is dependent upon the resistance of, and therefore the data state associated with, the memory cell. Thus, the data state of the memory cell may be determined by detecting whether the resistance of the memory cell 1830 corresponds to the high resistance state or the low resistance state, for example by comparison of the current on bit line 1860 with a suitable reference current by sense amplifiers of sense circuitry 1724.

The materials used in the embodiment described herein consist of silicon, silicon oxide and Ge₂Sb₂Te₅. Other dopants and other chalcogenides may be used as well. Chalcogens include any of the four elements oxygen (O), sulfur (S), selenium (Se), and Tellurium (Te), forming part of group VIA of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from group IVA of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable. The compositions can be characterized as TeₐGe_{b}Sb_{100-(a+b)}. One researcher has described the most useful alloys as having an average concentration of Te in the deposited materials well below 70%, typically below about 60%, and ranged in general from as low as about 23% up to about 58% Te and most preferably about 48% to 58% Te. Concentrations of Ge were above about 5% and ranged from a low of about 8% to about 30% average in the material, remaining generally below 50%. Most preferably, concentrations of Ge ranged from about 8% to about 40%. The remainder of the principal constituent elements in this composition was Sb. These percentages are atomic percentages that total 100% of the atoms of the constituent elements. (Ovshinsky U.S. Pat. No. 5,687,112, cols. 10-11.) Particular alloys evaluated by another researcher include Ge₂Sb₂Te₅, GeSb₂Te₄ and GeSb₄Te₇ (Noboru Yamada, “Potential of Ge—Sb—Te Phase-Change Optical Disks for High-Data-Rate Recording”, SPIE v.3109, pp. 28-37 (1997).) More generally, a transition metal such as chromium (Cr), iron (Fe), nickel (Ni), niobium (Nb), palladium (Pd), platinum (Pt) and mixtures or alloys thereof may be combined with Ge/Sb/Te to form a phase change alloy that has programmable resistive properties. Specific examples of memory materials that may be useful are given in Ovshinsky '112 at columns 11-13, which examples are hereby incorporated by reference.

Table I below illustrates possible compounds which can be found in the active region of a device having a composite SiO₂ and Si doped Ge₂Sb₂Te₅ memory material as described above. As can be seen, Si₂Te₃ has a higher melting point and a higher crystallization transition temperature than other possible compounds in the table. Thus, the formation of Si₂Te₃ in the active region tends to increase the melting point and increase the crystallization transition temperature of the memory material in the active region. This is believed to stabilize the active region, and suppress void formation.

TABLE 1

| | | Recrystallization |
|---|---|---|
| Possible Compound | Melting Temperature | Temperature |
| SiO₂ | 1726° C. | |
| Si | 1414° C. | |
| Ge | 938.3° C. | 520° C. |
| Si₂Te₃ | 885° C. | 290° C. |
| GeTe | 724° C. | 180° C. |
| Ge₂Sb₂Te₅ | 615° C. | 140° C. |
| Sb | 630° C. | X |
| Sb₂Te₃ | 617° C. | 97° C. |
| Sb₂Te | 547.5° C. | 95° C. |
| Te | 449.5° C. | 10° C. |

Table II below illustrates the bonding energy between silicon and the various elements of GeₓSb_{y}Te_{z}, Germanium, Antimony, Tellurium. As can be seen, the Silicon-Tellurium bond is stronger than the bonds formed with Tellurium and the other components of the memory material. As a result of the stronger bond, the endurance and data retention characteristics of the memory are improved.

TABLE 2

| | Energy |
|---|---|
| Bond | (KJmol⁻¹) |
| Ge—Ge | 264.4 ± 6.8 |
| Ge—Sb | X |
| Ge—Te | 396.7 ± 3.3 |
| Sb—Te | 277.4 ± 3.8 |
| Te—Te | 257.6 ± 4.1 |
| Sb—Sb | 301.7 ± 6.3 |
| Si—Ge | 297 |
| Si—Sb | X |
| Si—Te | 448 ± 8 |

As mentioned above, a variety of stable materials, such as dielectrics, with high mixing enthalpy can be utilized as dopants to reduce grain size, and segregate on grain boundaries while limiting void formation in the phase change material, including aluminum oxide, silicon carbide and silicon nitride. Also, a variety of reactive dopants can be used which tend to react with elements of the phase change material and suppress void formation in the active region. For chalcogenide based phase change material, reactive dopants of this kind can include materials that tend to bond strongly with Tellurium to form higher melting point compounds in the active region of the memory cell, including possibly Scandium, Titanium, Vanadium, Chromium, Manganese, Iron, and Gallium, and possibly other materials selected from elements 14 to 33 of the periodic table (except for the inert gas).

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device, comprising:
a first electrode and a second electrode; and
a phase change material between the first and second electrodes and having an active region, the phase change material having a first dopant characterized by tending to segregate from the phase change material on grain boundaries in the active region, and having a second dopant characterized by causing an increase in recrystallization temperature in the active region.

2. The device of claim 1, wherein the first dopant comprises a dielectric material.

3. The device of claim 1, wherein the phase change material comprises a chalcogenide and first dopant comprises material selected from silicon oxide, aluminum oxide, silicon carbide and silicon nitride.

4. The device of claim 1, wherein the phase change material comprises a chalcogenide and the first dopant is silicon dioxide having a concentration in a range of 10 to 20 at %.

5. The device of claim 1, wherein the second dopant comprises a material that bonds with an element of the phase change material with a bonding energy greater than a bonding energy between said element and other elements of the phase change material.

6. The device of claim 1, wherein the phase change material comprises a chalcogenide and the second dopant comprises a material selected from elements 14 to 33 of the periodic table.

7. The device of claim 1, wherein the phase change material comprises a chalcogenide and the second dopant comprises a material selected from Scandium, Titanium, Vanadium, Chromium, Manganese, Iron, and Gallium.

8. The device of claim 1, wherein the phase change material comprises a chalcogenide and the second dopant is silicon having a concentration in a range of 3 to 12 at %.

9. The device of claim 1, wherein the phase change material comprises GeₓSb_{y}Te_{z}, and the second dopant comprises a material which reacts with Te in the active region.

10. The device of claim 1, wherein the phase change material comprises GeₓSb_{y}Te_{z}; and wherein the first dopant is silicon oxide and the second dopant is silicon.

11. A method for manufacturing a memory device, the method comprising:
forming a first electrode and a second electrode;
forming a phase change material between the first and second electrodes and having an active region, the phase change material having a first dopant characterized by tending to segregate from the phase change material on grain boundaries in the active region, and having a second dopant characterized by causing an increase in recrystallization temperature of the phase change material in the active region; and
heating said active region to cause the first dopant to segregate from the phase change material within the active region.

12. The method of claim 11, wherein the first dopant comprises a dielectric material.

13. The method of claim 11, wherein the phase change material comprises a chalcogenide and first dopant comprises material selected from silicon oxide, aluminum oxide, silicon carbide and silicon nitride.

14. The method of claim 11, wherein the phase change material comprises a chalcogenide and the first dopant is silicon dioxide having a concentration in a range of 10 to 20 at %.

15. The method of claim 11, wherein the second dopant comprises a material that bonds with an element of the phase change material with a bonding energy greater than a bonding energy between said element and other elements of the phase change material.

16. The method of claim 11, wherein the phase change material comprises a chalcogenide and the second dopant comprises a material selected from elements 14 to 33 of the periodic table.

17. The method of claim 11, wherein the phase change material comprises a chalcogenide and the second dopant comprises a material selected from Scandium, Titanium, Vanadium, Chromium, Manganese, Iron, and Gallium.

18. The method of claim 11, wherein the phase change material comprises a chalcogenide and the second dopant is silicon having a concentration in a range of 3 to 12 at %.

19. The method of claim 11, wherein the phase change material comprises GeₓSb_{y}Te_{z}, and the second dopant comprises a material which reacts with Te in the active region.

20. The method of claim 11, wherein the phase change material comprises GeₓSb_{y}Te_{z}; and wherein the first dopant is silicon oxide and the second dopant is silicon.

21. A memory device comprising:
a first electrode and a second electrode; and
a chalcogenide between the first and second electrodes, the chalcogenide having a first dopant which comprises a dielectric material, and having a second dopant which comprises a material selected from elements 14 to 33 of the periodic table.

22. The device of claim 21, wherein the first dopant comprises material selected from silicon oxide, aluminum oxide, silicon carbide and silicon nitride, and the second dopant comprises a material selected from Silicon, Scandium, Titanium, Vanadium, Chromium, Manganese, Iron, and Gallium.

23. The device of claim 22, wherein the chalcogenide comprises GeₓSb_{y}Te_{z}, having a bulk stoichiometry where x=2, y=2 and z=5.

24. A memory device, comprising:
a first electrode and a second electrode;
GeₓSb_{y}Te_{z} between the first and second electrodes, the GeₓSb_{y}Te_{z} having a first dopant material comprising silicon oxide and a second dopant comprising silicon.

25. The device of claim 24, wherein the GeₓSb_{y}Te_{z} has a bulk stoichiometry where x=2, y=2 and z=5.

26. A memory device, comprising:
a first electrode and a second electrode; and
a phase change material between the first and second electrodes and having an active region, the phase change material having a first dopant characterized by tending to segregate from the phase change material on grain boundaries in the active region, and having a second dopant characterized by suppressing void formation in the phase change material inside the active region.
